(19) United States
(12) Patent Application Publication
(10) Pub. No.: US 2013/0256246 A1
(43) Pub. Date: Oct. 3, 2013

(54) RACKING SYSTEM FOR SUPPORTING A PLURALITY OF SOLAR PANELS

(71) Applicant: Efrem Tagliamonte, Hyde Park, NY (US)

(72) Inventor: Efrem Tagliamonte, Hyde Park, NY (US)

(73) Assignee: GENERAL ELECTRIC COMPANY, Schenectady, NY (US)

(21) Appl. No.: 13/431,352

(22) Filed: Mar. 27, 2012

(51) Int. Cl. H01L 23/32

(52) U.S. Cl. 211/41.1

(57) ABSTRACT

A rack support assembly for use with a racking system including a support post and a racking assembly for supporting a plurality of solar panels is disclosed. The rack support assembly may generally include a sleeve extending between a first end and a second end. The first end of the sleeve may be configured to be received on the support post. In addition, the rack support assembly may include a rack support member coupled to the sleeve so as to extend from the second end of the sleeve. The rack support member may be configured to be coupled to a portion of the racking assembly.

### FIELD OF THE INVENTION

The present subject matter relates generally to a racking system for supporting a plurality of solar panels relative to a support surface and, more particularly, to a rack support configured for use with such a racking system.

### BACKGROUND OF THE INVENTION

Solar power is considered one of the cleanest, most environmentally friendly energy sources presently available, and solar panel arrays have gained increased attention in this regard. Typically, the racking system for a ground-mounted solar panel array includes an upper assembly configured to support the solar panels and one or more foundation posts coupled between the upper assembly and the ground. The coupling between the upper assembly and the foundation posts typically requires a strong mechanical bound and multiple degrees of freedom to allow for site variation and tolerances.

Conventional racking systems rely on foundation posts having holes or slots defined therein in order to couple the posts to the upper assembly. As such, these racking systems require precise alignment between the posts and the upper assembly, which increases the complexity and cost of machining such components. Additionally, this configuration typically limits the degrees of freedom between the posts and the upper assembly. Accordingly, there is a need for a simple, cost effective means for coupling foundation posts to the upper assembly of a racking system configured for supporting a plurality of solar panels.

### BRIEF DESCRIPTION OF THE INVENTION

Aspects and advantages of the invention will be set forth in part in the following description, or may be obvious from the description, or may be learned through practice of the invention.

In one aspect, the present subject is directed to a rack support for use with a racking system including a post and a racking assembly for supporting a plurality of solar panels. The rack support may generally include a sleeve extending between a first end and a second end. The first end of the sleeve may be configured to be received on the post. In addition, the rack support may include a support member coupled to the sleeve so as to extend outwardly from the second end of the sleeve. The support member may be configured to be coupled to a portion of the racking assembly.

In another aspect, the present subject matter is directed to a racking system for supporting a plurality of solar panels relative to a support surface. The racking system may generally include a post extending from the support surface and a racking assembly coupled to the plurality of solar panels. In addition, the racking system may include a rack support coupled between the post and the racking assembly. The rack support may generally include a sleeve extending between a first end and a second end. The first end of the sleeve may be configured to be received on the post. In addition, the rack support may include a support member coupled to the sleeve so as to extend outwardly from the second end of the sleeve. The support member may be configured to be coupled to a portion of the racking assembly.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 illustrates a perspective view of one embodiment of a racking system for supporting a plurality of solar panels;

FIG. 2 illustrates a side view of the racking system shown in FIG. 1;

FIG. 3 illustrates a perspective, exploded view of one embodiment of a rack support suitable for use in the system shown in FIGS. 1 and 2;

FIG. 4 illustrates an assembled view of the rack support shown in FIG. 3;

FIG. 5 illustrates a partial cross-sectional view of the rack support shown in FIG. 4 after it has been coupled to one of the rails of the racking assembly of the disclosed racking system;

FIG. 6 illustrates a perspective, exploded view of another embodiment of a rack support suitable for use in the system shown in FIGS. 1 and 2; and

FIG. 7 illustrates an assembled view of the rack support shown in FIG. 6.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

In general, the present subject matter discloses a racking system for supporting a plurality of solar panels relative to a support surface. Specifically, the present subject matter discloses a rack support configured for use with a racking system. In several embodiments, the rack support may include a sleeve and a support member coupled to the sleeve. The sleeve may be configured to be received onto a support post of the racking system and the support member may be configured to be coupled to a portion of the racking assembly.

As will be apparent from the description below, the disclosed rack support provide a simple, cost effective means for coupling supports posts to a racking assembly of a racking system. Specifically, the components of the rack support may be fabricated from industry standard materials, thereby allowing flexibility in manufacturing and reducing manufacturing costs. Additionally, the configuration of the rack support eliminates the need for secondary machining and/or drilling when coupling the supports posts to the racking assembly. As such, installation may be simplified, thereby lowering installation costs. Moreover, in several embodiments, each rack support may include a circular sleeve configured to be received onto one of the circular support posts of the racking system. As such, the rack support may be rotated relative to the support posts, thereby providing 360 degrees of freedom for adjusting the orientation of the rack support and/or the racking assembly.

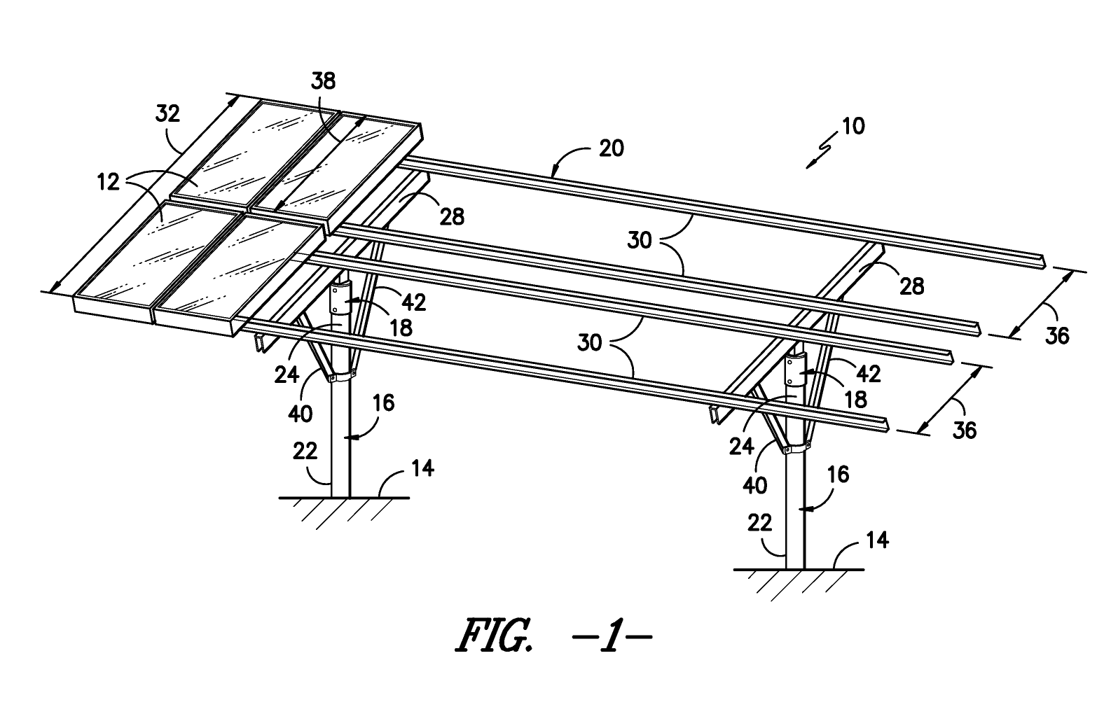

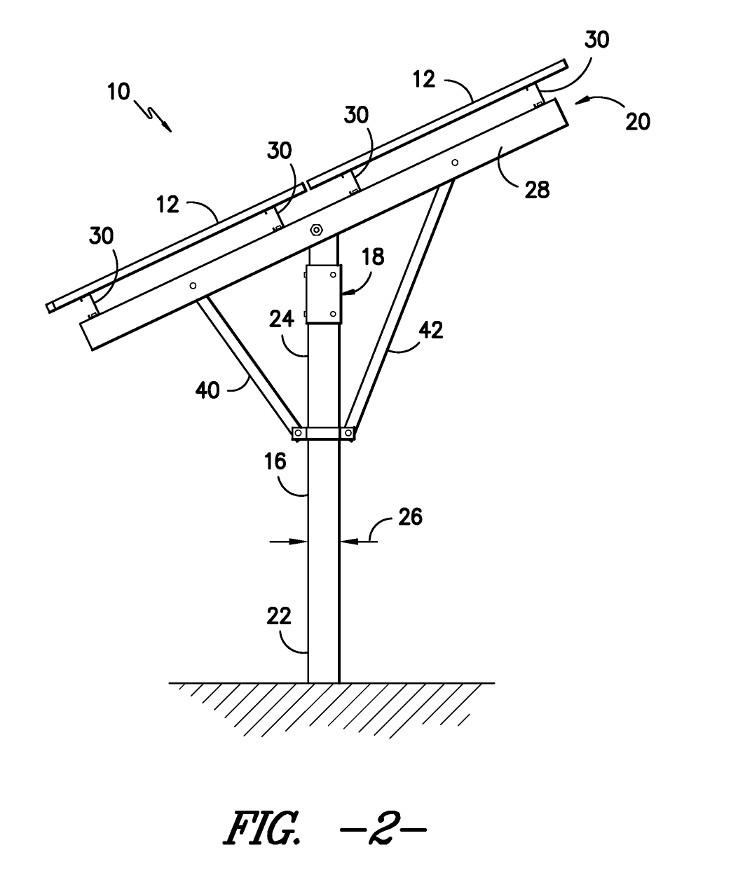

Referring now to the drawings, FIGS. 1 and 2 illustrate one embodiment of a racking system 10 for supporting an array of solar panels 12 relative to a support surface 14, such as the ground and/or a concrete base. In particular, FIG. 1 illustrates a perspective view of the racking system 10 and FIG. 2 illustrates a side view of the racking system 10. It should be appreciated that disclosed racking system 10 has been shown with only a few solar panels 12 installed thereon in order to illustrate the various components of the racking system 10.

As shown, the racking system 10 may generally include one or more support posts 16, a corresponding number of rack supports 18 and a racking assembly 20 coupled to the rack support(s) 18. In general, the support post(s) 16 may be configured to provide vertical support for the racking system 10. In addition, the support post(s) 16 may be configured to position the solar panels 12 a suitable distance from the support surface 14. For example, as shown in FIGS. 1 and 2, each support post 16 may extend longitudinally between a first end 22 and a second end 24, with the first end 22 being coupled to the support surface 14 and the second end 24 being coupled to one of the rack supports 18.

It should be appreciated that, in general, the first end 22 of each support post 16 may be coupled to the support surface 14 using any suitable means and/or method known in the art. For instance, in embodiments in which the support surface 14 comprises the ground, the first end 22 of each support post 16 may simply be driven into the ground a suitable depth. Alternatively, in embodiments in which the support surface 14 comprises a concrete pad or other suitable hard-drying material, the first end 22 of each support post 16 may be encased within the concrete or other suitable material in order to couple the support post 16 to the support surface 14.

Additionally, it should be appreciated that each support post 16 may generally have any suitable geometric configuration that permits it to function as described herein. For instance, in one embodiment, each support post 16 may have a circular cross-sectional shape and may define any suitable diameter 26. However, in other embodiments, the support post(s) 16 may have any other suitable cross-sectional shape, such as a rectangular cross-sectional shape.

Referring still to FIGS. 1 and 2, the racking assembly 20 may generally be configured to support the array of solar panels 12 above the support surface 14. Thus, it should be appreciated that the racking assembly 20 may generally include any number and/or combination of rails, beams and/or other suitable support members that permit the racking assembly 20 to function as described herein. For instance, as shown in the illustrated embodiment, the racking assembly 10 may include a plurality of interconnected rails 28, 30, such as one or more cross-wise rails 28 and one or more panel rails 30.

As shown in the illustrated embodiment, each cross-wise rail 28 of the racking assembly 20 may be configured to be coupled to one of the rack supports 18 such that the rail 28 extends longitudinally along a width 32 of the racking system 10. For instance, as particularly shown in FIG. 2, in one embodiment, each cross-wise rail 28 may be coupled to its corresponding rack support 18 at a location generally equidistant from the ends of the rail 28. However, in other embodiments, the cross-wise rails 28 may be coupled to rack supports 18 at any other suitable location along their length.

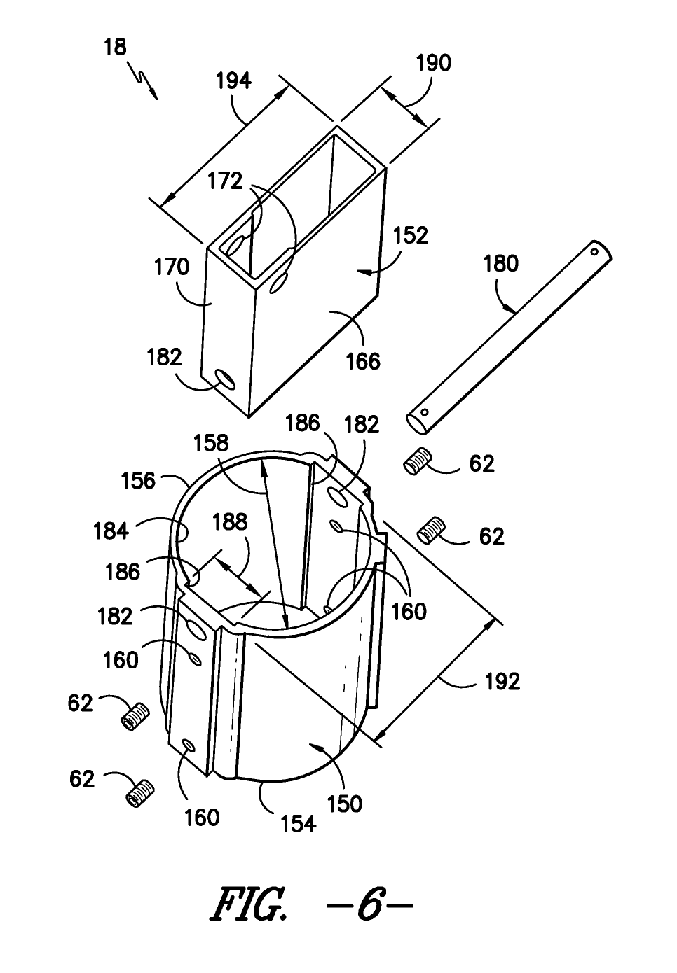

It should be appreciated that the cross-wise rails 28 may generally be configured to be coupled to the rack supports 18 using any suitable means and/or method known in the art, such as by coupling each cross-wise rail 28 to its corresponding rack support 18 using suitable mechanical fasteners and/or by welding each cross-wise rail 28 to its corresponding rack support 18. For instance, as will be described below with reference to FIG. 5, in one embodiment, each cross-wise rail 28 may be configured to receive a portion of its corresponding rack support 18 such that a suitable mechanical fastener (e.g., a pin) may be inserted through both the cross-wise rail 28 and the rack support 18, thereby coupling such components together. Moreover, in one embodiment, the cross-wise rails 28 may be configured to be rotatably or hingedly coupled to each rack support 18. As such, the orientation of the cross-wise rails 28 relative to the rack supports 18 may be varied, thereby permitting the orientation of the solar panels 12 relative to the support surface 14 to be adjusted. However, it should be appreciated that, in alternative embodiments, the cross-wise rails 28 may be configured to be fixedly attached to each rack support 18.

Additionally, in several embodiments, the panel rails 30 of the racking assembly 20 may be configured to be coupled to the cross-wise rails 28 using any suitable means and/or method known art, such as by coupling the panel rails 30 to the cross-wise rails 28 using suitable mechanical fasteners and/or by welding the panel rails 30 to the cross-wise rails 28. For instance, as shown in FIGS. 1 and 2, the panel rails 30 may be coupled across the cross-wise rails 28 using suitable fasteners (e.g., a bracket/bolt combination) such that the panel rails 30 extend lengthwise generally perpendicular to the cross-wise rails 28.

Moreover, the panel rails 30 may also be configured to be spaced apart from one another along the width 32 of the racking system 10 so as to provide a means for coupling the solar panels 12 to the racking assembly 20. For example, as shown in FIGS. 1 and 2, in one embodiment, the racking assembly 20 may include two pairs of panel rails 30 for mounting two rows of solar panels 12 across the assembly 20. In such an embodiment, the panel rails 30 in each pair may generally being spaced apart from one another a distance 36 that is generally equal to or less than a width 38 of each solar panel 12. However, it should be appreciated that, in alternative embodiments, the racking assembly 20 may include any number of panel rails 30 for mounting any suitable number of rows of solar panels 12 across the assembly 20.

It should also be appreciated that the rails 28, 30 of the racking assembly 20 may generally have any suitable geometric configuration that allows such components to function as described herein. For instance, in one embodiment, the cross-wise rails 28 and/or the panel rails 30 may define a partially rectangular or “C-shaped” cross-sectional shape, such as that shown in FIG. 5. However, in other embodiments, the cross-wise rails 28 and/or the panel rails 30 may have any other suitable cross-sectional shape, such as a full rectangular cross-sectional shape, a circular cross-sectional shape, an I-beam cross-sectional shape and/or any other suitable shape.

Additionally, it should be appreciated that the support posts 16 and racking assembly 20 shown in FIGS. 1 and 2 are merely illustrated to provide one example of how such components may be configured for use in a racking system 10 for supporting an array solar panels 12. Thus, one of ordinary skill in the art should readily appreciate that the present subject matter need not be limited to any particular configuration for the support posts 16 and racking assembly 20.

Referring still to FIGS. 1 and 2, in several embodiments, the racking system 10 may also include one or more support arms 40, 42 configured to be coupled between each support post 16 and the racking assembly 20. For example, as shown in the illustrated embodiment, the racking system 10 may include first and second support arms 40, 42 extending between each cross-wise rail 28 and its corresponding support post 16. In general, the support arms 40, 42 may be configured to provide additional vertical support for the racking assembly 20. For instance, in embodiments in which the cross-wise rails 28 are rotationally or hingedly coupled to the rack supports 18, the support arms 40, 42 may be configured to support the cross-wise rails 28 at a fixed orientation relative to the rack supports 18, thereby maintaining the solar panels 12 at a fixed orientation relative to the support surface 14.

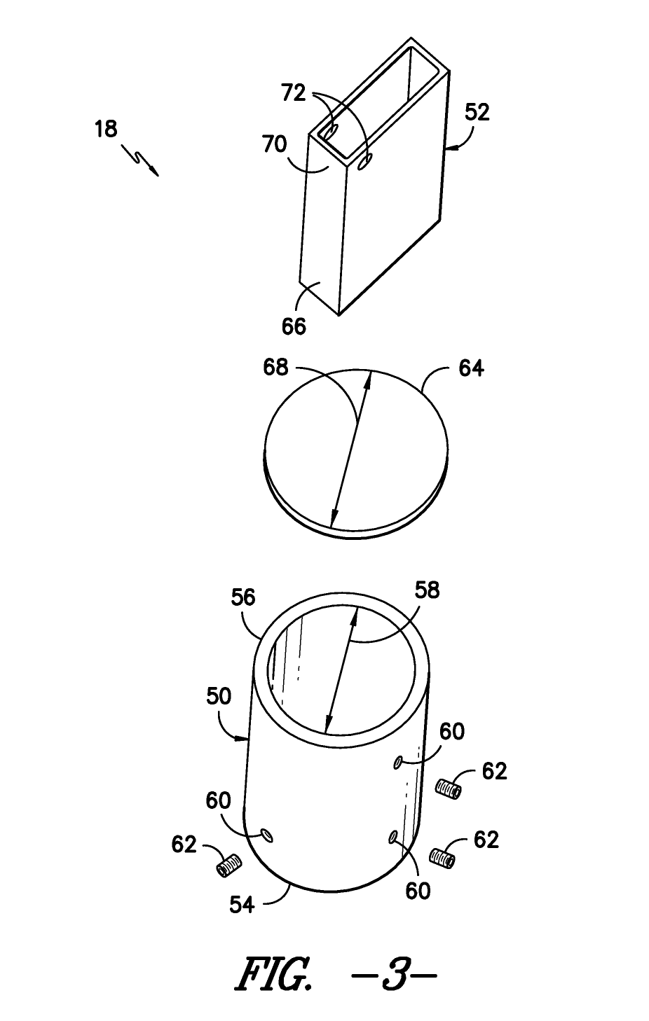

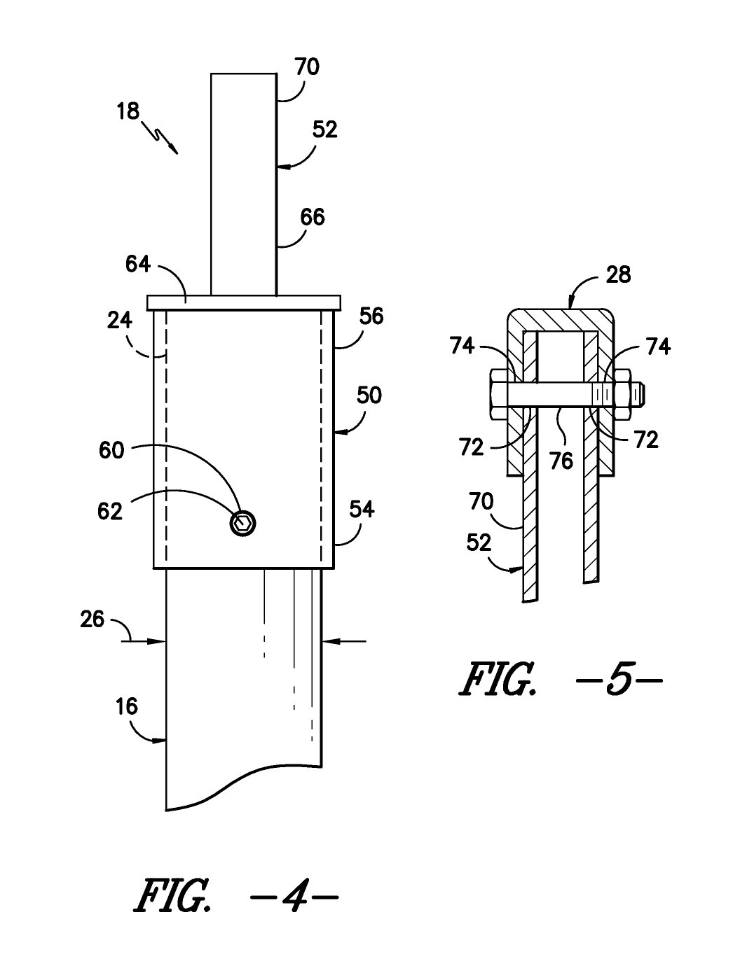

Referring now to FIGS. 3-5, several views of one of the rack supports 18 of the disclosed racking system 10 are illustrated in accordance with aspects of the present subject matter. Specifically, FIG. 3 illustrates an exploded view of the rack support 18 and FIG. 4 illustrates an assembled view of the rack support 18 installed onto one of the support posts 16 of the racking system 10. In addition, FIG. 5 illustrates a cross-sectional view of a portion of the rack support 18 after it has been coupled to one of the cross-wise rails 28 of the racking assembly 20.

In general, the disclosed rack supports 18 may be configured as attachment interfaces for coupling the racking assembly 20 to the support posts 16. As shown in the illustrated embodiment, each rack support 18 may include a sleeve 50 and a support member 52 configured to be coupled to the sleeve 50. The sleeve 50 of each rack support 18 may generally be configured to be coupled to one of the support posts 16. For example, in several embodiments, the sleeve 50 may comprise a hollow body extending between a first end 54 and a second end 56, with the first end 54 of the sleeve 50 being configured to be received onto the second end 24 of one of the support post 16. Specifically, as shown in FIGS. 3 and 4, in one embodiment, the sleeve 50 may be configured to define a circular cross-sectional shape between its first and second ends 54, 56 having an inner diameter 58 that is slightly larger than the diameter 26 of the support posts 16. As such, the first end 54 of sleeve 50 may be slid over and received onto the second end 24 of its corresponding support post 16. However, in other embodiments, the sleeve 50 may define any other suitable cross-sectional shape that permits it to be coupled to one of the support posts 16.

Additionally, in several embodiments, the sleeve may include a plurality of openings 60 configured to receive suitable mechanical fasteners for securing the sleeve 50 to its corresponding support post 16. For example, as shown in FIGS. 3 and 4, openings 60 may be defined through the sleeve 50 at various locations around its circumference. As such, after the sleeve 50 has been received onto the second end 24 of one of the support posts 16, a plurality of set screws 62 and/or other suitable fasteners may be threaded into or otherwise inserted through the openings 60 in order to secure the sleeve 50 to the support post 16.

Moreover, the sleeve 50 may also be configured to be coupled to the support member 52 of the rack support 18 using any suitable attachment means and/or method known in the art. For instance, in several embodiments, a connector plate 64 may be utilized to couple the sleeve 50 to the support member 62. The connector plate 64 may, in one embodiment, comprise a flat disc configured to be secured directly between the second end 56 of the sleeve 50 and a bottom portion 66 of the support member 52. For instance, as shown in the illustrated embodiment, the connector plate 64 define a diameter 68 that is larger than the inner diameter 58 of the sleeve 50 such that the connector plate 64 may be secured over the second end 56 of the sleeve 50, such as by welding the connector plate 64 to the second end 56 of the sleeve 50 and/or by using suitable mechanical fasteners to couple the connector plate 64 to the second end 56. Similarly, as shown in FIG. 4, the bottom portion 66 of the support member 52 may be coupled to the opposing side of the connector plate 64, such as by welding the bottom portion 66 of the support member 52 to the opposing side of the connector plate 64 or by coupling the bottom portion 66 to the opposing side using any suitable mechanical fasteners. As such, that the support member 52 may generally extend outwardly from the connector plate 64 and/or the second end 56 of the sleeve 50.

It should be appreciated that, in addition to coupling the sleeve 50 to the support member 52, the connector plate 64 may also serve as a positive stop for the second end 24 of the support post 16 within the sleeve 50. As such, the connector plate 64 may indicate when the sleeve 50 has been fully installed onto its corresponding support post 16. Moreover, it should be appreciated that, in one embodiment, one or more shims (not shown) may be positioned within the sleeve 50 between the second end 24 of the support post 16 and the connector plate 64 in order to adjust the positioning of the sleeve 50 relative to the support post 16. For instance, the shim(s) may comprise flat, disc-shaped plates having a diameter that is less than the inner diameter 58 of the sleeve 50.

Referring still to FIGS. 3-5 the support member 52 may generally be configured to be coupled to a portion of the racking assembly 20, such as by being coupled to one of the cross-wise rails 28 of the racking assembly 20. For instance, in several embodiments, a top portion 70 of the support member 52 may be configured to be received within a portion of one of the cross-wise rails 28. Specifically, as shown in FIGS. 3 and 5, in one embodiment, the support member 52 may define a rectangular cross-sectional shape configured to be received within a corresponding partially rectangular or C-shaped profile of the cross-wise rails 28. In such an embodiment, the top portion 70 of the support member 52 may be secured within its corresponding cross-wise rail 28 using any suitable attachment means and/or method known in the art, such as by welding the support member 50 within its corresponding cross-wise rail 28 and/or by coupling the support member 50 within its corresponding cross-wise rail 28 using suitable mechanical fasteners. For instance, as shown in FIGS. 3 and 5, the support member 52 may define one or more openings 72 configured to be aligned with one or more corresponding openings 74 defined in the cross-wise rail 28 when the top portion 70 of the support member 52 is received within the cross-wise rail 28. As such, one or more suitable mechanical fasteners 76 may be inserted through the aligned openings 72, 74 in order to couple the support 52 member to its corresponding cross-wise rail 28. For example, as indicated above, it may be desirable for the cross-wise rails 28 to be rotatably or hingedly coupled to the rack supports 18. In such an embodiment, a pin, bolt and/or any other suitable rotational or hinged attachment mechanism may be inserted through the aligned openings 72, 74 so as to rotatably or hingedly couple the cross-wise rails 28 to the top portions 70 of the support members 52.

It should be appreciated that, in alternative embodiments, the support member 52 and/or the cross-wise rails 28 may have any other suitable configuration that permits such components to be secured to one another. For instance, in another embodiment, the top portion 70 of the support member 62 may include a channel or groove configured to receive a portion of one of the cross-wise rails 28.

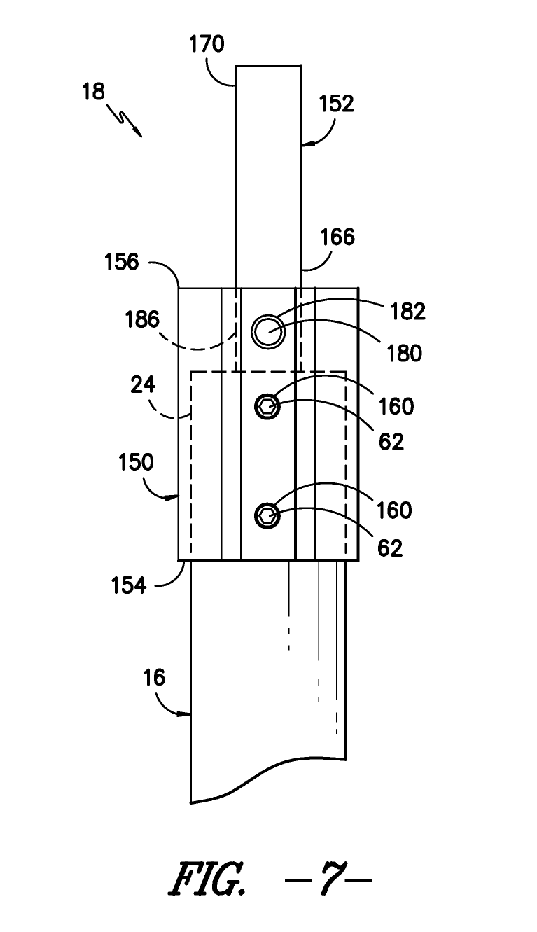

Referring now to FIGS. 6 and 7, another embodiment of a rack support 118 for coupling the support posts 16 to the racking assembly 20 of the disclosed racking system 10 is illustrated in accordance with aspects of the present subject matter. Specifically, FIG. 6 illustrates an exploded view of the rack support 118 and FIG. 7 illustrates an assembled view of the rack support 118 installed onto one of the support posts 16.

In general, the rack support 118 shown in FIGS. 6 and 7 may be configured similar to the rack support 18 described above with reference to FIGS. 3-5. In particular, the rack support 118 may include a sleeve 150 configured to be coupled to one of the support posts 16. For instance, as shown in the illustrated embodiment, the sleeve 150 may comprise a hollow body defining a circular cross-sectional shape between its first and second ends 154, 156 such that the sleeve 150 may be received onto the second end 24 of its corresponding support post 16. In addition, the sleeve 150 may include a plurality of spaced apart openings 160 configured to receive suitable mechanical fasteners (e.g., set screws 62) for securing the sleeve 150 to the support post 16.

Moreover, the rack support 118 may also include a support member 152 configured to be coupled to a portion of the racking assembly 20. For instance, as shown in the illustrated embodiment, the support member 152 may define a rectangular cross-sectional shape such that a top portion 170 of the support member 152 may be received within a correspondingly shaped portion of one of the cross-wise rails 28, such as that shown in FIG. 5. Further, as shown in FIG. 6, the support member 152 may define one or more openings 172 configured to be aligned with one or more corresponding openings 74 (FIG. 5) defined in the cross-wise rail 28 when the top portion 170 of the support member 152 is received within the cross-wise rail 28. As such, one or more suitable mechanical fasteners 76 (FIG. 5) may be inserted through the aligned openings 172, 74 in order to hingedly or fixedly attached to the support member 152 to its corresponding cross-wise rail 28.

Additionally, similar to the embodiment described above, the sleeve 150 and support member 152 may also be configured to be coupled to one another. However, unlike the connector plate 64, a pinned connection may be utilized to couple the support member 152 to the sleeve 150. Specifically, in several embodiments, a bottom portion 166 of the support member 152 may be configured to be received within the sleeve 150 such that a pin 180 or other suitable mechanical fastener may be utilized to couple the sleeve 150 to the support member 152. For instance, as shown in the illustrated embodiment, the bottom portion 166 of the support member 152 and the second end 156 of the sleeve 150 may each define a through hole 182 configured to receive the pin 180 (or other suitable mechanical fastener). Moreover, in one embodiment, an inner surface 184 of the sleeve 150 may be configured to define first and second recessed channels 186 for receiving the support member 152. For example, as shown in FIG. 6, the recessed channels 186 may generally define a width 188 that is greater than a width 190 of the support member 152. Similarly, the recessed channels 186 may be formed within the inner surface 184 to a sufficient depth such that a distance 192 defined between the recessed channels 186 is greater than a cross-wise length 194 of the support member 152. Accordingly, the bottom portion 166 of the support member 152 may be inserted within the sleeve 150 along the recessed channels 186 until the through-hole 182 defined in the support member 152 is aligned with the through-hole 182 defined in the sleeve 150. The pin 180 (or other suitable mechanical fastener) may then be inserted through the aligned through-holes 182 in order to couple the sleeve 150 to the support member 152.

It should be appreciated that, in the embodiment shown in FIGS. 6 and 7, the bottom portion 166 of the support member 152 may generally serve as a positive stop within the sleeve 150 for the second end 24 of the support post 16. As such, the second end 24 of the support post 16 may contact the bottom portion 166 of the support member 152 when the sleeve 150 is fully installed onto the support post 16. Moreover, it should be appreciated that, in one embodiment, one or more shims (not shown) may be positioned within the sleeve 150 between the second end 23 of the support post 16 and the bottom portion 166 of the support member 152 in order to adjust the positioning of the sleeve 150 relative to the support post 16. For instance the shim(s) may comprise flat, disc-shaped plates having a diameter that is less than an inner diameter 158 of the sleeve 150.

Additionally, it should be appreciated that the disclosed sleeves 50, 150 and support members 52, 152 may generally be formed from any suitable material. For instance, in embodiments in which the sleeves 50, 150 are configured to be welded to the support members 52, 152 (either directly or indirectly (e.g., via the connector plate 64)), the sleeves 50, 150 and support members 52, 152 may be formed from a weldable metal, such as steel, or any other suitable material. Similarly, in embodiments in which the sleeves 50, 150 are configured to be coupled to the support members 52, 152 using mechanical fasteners (e.g., the pin 180), the sleeves 50, 150 and support members 52, 152 may be formed from various other materials, such as aluminum and other suitable materials.

Moreover, it should be appreciated that, although only a couple of examples for coupling the sleeves 50, 150 to support members 52, 152 have been illustrated herein (e.g., using the connector plate 64 (FIGS. 3 and 4) or using a pinned connection (FIGS. 6 and 7)), the sleeves 50, 150 may coupled to the support members 52, 152 using any other suitable attachments means and/or method that permits such components to function as described herein.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A rack support for use with a racking system including a post and a racking assembly for supporting a plurality of solar panels, the rack support comprising:
a sleeve extending between a first end and a second end, the first end of the sleeve being configured to be received on the post; and
a support member coupled to the sleeve so as to extend outwardly from the second end of the sleeve, the support member being configured to be coupled to a portion of the racking assembly.

2. The rack support of claim 1, further comprising a plate coupled between the second end of the sleeve and the support member.

3. The rack support of claim 2, wherein the plate is welded between the second end of the sleeve and the support member.

4. The rack support of claim 1, wherein the sleeve includes an inner surface, the inner surface defining at least one recessed channel.

5. The rack support of claim 4, wherein a portion of the support member is configured to be received within the at least one recessed channel.

6. The rack support of claim 1, wherein the sleeve and the support member define corresponding through-holes configured to be aligned with one another, further comprising a pin configured to extend through the aligned through-holes in order to couple the support member to the sleeve.

7. The rack support of claim 1, wherein the sleeve defines a plurality of openings, each of the plurality of openings being configured to receive a mechanical fastener for coupling the sleeve to the support post.

8. The rack support of claim 1, wherein the sleeve defines a substantially circular cross-sectional shape.

9. The rack support of claim 1, wherein the support member defines a substantially rectangular cross-sectional shape.

10. A racking system for supporting a plurality of solar panels relative to a support surface, the system comprising:
a post extending from the support surface;
a racking assembly coupled to the plurality of solar panels; and
a rack support coupled between the post and the racking assembly, the rack support comprising:
a sleeve extending between a first end and a second end, the first end of the sleeve being configured to be received on the post; and
a support member coupled to the sleeve so as to extend outwardly from the second end of the sleeve, the support member being configured to be coupled to a portion of the racking assembly.

11. The racking system of claim 10, further comprising a plate coupled between the second end of the sleeve and the support member.

12. The racking system of claim 11, wherein the plate is welded between the second end of the sleeve and the support member.

13. The racking system of claim 10, wherein the sleeve includes an inner surface, the inner surface defining at least one recessed channel.

14. The racking system of claim 13, wherein a portion of the support member is configured to be received within the at least one recessed channel.

15. The racking system of claim 10, wherein the sleeve and the support member define corresponding through-holes configured to be aligned with one another, further comprising a pin configured to extend through the aligned through-holes in order to couple the support member to the sleeve.

16. The racking system of claim 10, wherein the sleeve defines a plurality of openings, each of the plurality of openings being configured to receive a mechanical fastener for coupling the sleeve to the support post.

17. The racking system of claim 10, wherein the sleeve and the support post both define a substantially circular cross-sectional shape.

18. The racking system of claim 10, wherein the racking assembly includes at least one cross-wise rail, the at least one cross-wise rail being configured to be coupled to the support member.

19. The racking system of claim 18, wherein the support member is configured to be received within a portion of the at least one cross-wise rail.

20. The racking system of claim 18, wherein the support member is pivotally coupled to the at least one cross-wise rail.
